(19) United States
(12) Patent Application Publication
(10) Pub. No.: US 2011/0045628 A1
(43) Pub. Date: Feb. 24, 2011

(54) METHOD OF THERMOCLEAVING A POLYMER LAYER

(75) Inventor: Frederik Christian Krebs, Lyngby (DK)

Correspondence Address: PILLSBURY WINTHROP SHAW PITTMAN, LLP, P.O. BOX 10500, MCLEAN, VA, 22102, US

(73) Assignee: THE TECHNICAL UNIVERSITY OF DENMARK, Kgs. Lyngby (DK)

(21) Appl. No.: 12/918,296

(22) PCT Filed: Feb. 17, 2009
(86) PCT No.: PCT/EP2009/051866

§ 371 Date: Oct. 21, 2010

(30) Foreign Application Priority Data
Feb. 18, 2008 (GB) 0802934.0
Apr. 21, 2008 (GB) 0807211.8
Jun. 6, 2008 (GB) 0810379.8

(51) Int. Cl. H01L 51/48

(52) U.S. Cl. 438/82; 257/E51.012

(57) ABSTRACT

A method of thermocleaving a thermocleavable polymer layer which is in thermal contact with a heat sensitive component that is not tolerant of the temperature required for thermocleavage of the thermocleavable polymer layer, in which the thermocleavable polymer layer is illuminated with a light source having a wavelength range more strongly absorbed by the thermocleavable polymer and substantially less strongly absorbed by the heat sensitive component, such that the thermocleavable polymer layer reaches a temperature sufficient to cause thermocleavage of the polymer without causing detrimental heating to the heat sensitive component. Further provided is apparatus for carrying out the above method.

The present invention relates to a method of targeted thermocleavage of a thermocleavable polymer layer in the presence of a heat sensitive substance, i.e. a substance sensitive to the temperature required for thermocleavage of the thermocleavable polymer, and apparatus for carrying out the method. It is particularly, but not exclusively, applicable to the manufacture of polymer solar cells.

Solar power is an important renewable energy source, and can be harvested using photovoltaic cells (solar cells). Renewable energy sources are desirable for a number of reasons. First, such energy sources enable a reduction in consumption of non-renewable energy sources. Second, such energy sources enable the use of electrical devices without the need for a mains power source. This is of particular interest in remote locations, for example at sea or in developing countries.

In solar cells, photons are absorbed and the energy of the photon forms an exciton consisting of an electron and a hole which initially are bound together. These can be separated into free charge carriers and caused to migrate towards respective electrodes by an electric field, suitably produced by electrodes of differing work functions. Cells containing two components (heterojunction cells) can give much higher efficiency than cells containing a single component because of increased charge separation at the interface between the two components.

In electroluminescent devices, which can also be photovoltaic devices, electrons and holes injected at opposed electrodes reach one another by conduction and recombine to produce light.

Solar cells may rely on photovoltaic polymers. It has been recognised that potentially such devices have advantages over the conventional, similar devices based on inorganic semiconductors. These potential advantages include cheapness of the materials and versatility of processing methods, flexibility (lack of rigidity) and toughness. In particular, there is the potential advantage of high volume production at low unit cost.

Photovoltaic polymers can be derived from chemically doped conjugated polymers, for example partially oxidised (p-doped) polypyrrole. The article ‘Conjugated polymers: New materials for photovoltaics’, Wallace et al, Chemical Innovation, April 2000, Vol. 30, No. 1, 14-22 reviews the field.

The present inventors have appreciated that, in order to produce polymer solar cells on a commercial basis, it is important to be able to make large cells or combinations of cells.

Fréchet et al. (WO2005/107047) have disclosed polymer solar cells containing a layer of metal oxide and a layer of thermocleavable polythiophene.

Risø National Laboratory (GB2424512) has disclosed the use of a thermocleavable polythiophene layer and a fullerene layer in polymer solar cells.

The present inventors have also found that a mixture of metal oxide nanoparticles and thermocleavable polythiophene may be used in polymer solar cells.

In order to achieve large area processing for solar cells, i.e. the ability to produce large cells or combinations of cells, the present inventors have explored the use of solution printing techniques to create the active layers of solar cells. In particular, they have disclosed the use of thermocleavable polythiophenes, as stated above. The thermocleavable polythiophenes may bear thermocleavable solubilising groups such as long alkyl chain ester groups, in particular tertiary alkyl ester groups. Thus, the polythiophene may be dissolved in a suitable solvent in order to be applied by a solution printing technique in the manufacture of the solar cell, and then heat treated to remove the solubilising groups, thus rendering the polythiophene layer less soluble and allowing the solution printing of further layers thereon without disruption or damage to the polythiophene layer.

In order to cleave an alkyl side chain from a carboxylate-substituted polythiophene (eg poly(3-(2-methylhex-2-yl)oxycarbonyldithiophene) (P3 MHOCT), which cleaves to poly(3-carboxydithiophene) (P3CT), poly-[(3′-(2,5,9-trimethyldecan-2-yl)-oxy-carbonyl)-[2,2′; 5′,2″]terthiophene-1,5″-diyl)-co-(2,3-diphenylthieno[3,4-b]pyrazine-5,7-diyl)](P3TMDCTTP), which cleaves to poly(carboxyterthiophene-co-diphenylthienopyrazine) (P3CTTP)), or poly-[(3′-(2,5,9-trimethyldecan-2-yl)-oxy-carbonyl)-[2,2′; 5′,2″]terthiophene-1,5″-diyl)-co-(benzo[c][1,2,5]thiadiazole-4,7-diyl)] (P3TMDCTBT), which cleaves to poly-[carboxyterthiophene-co-(benzothiadiazole] (P3CTBT), it is necessary to heat the polymer to a temperature of between 150° C. and 250° C., such as 210° C. Below 150° C. the rate of cleavage is impractically slow for a commercial process. In addition, it may be preferred to cleave also the carboxylate groups from the polymer to arrive at an unsubstituted polythiophene (eg polythiophene (PT), poly(thiophene-co-diphenylthienopyrazine) (PTTP), or poly(thiophene-co-benzothiadiazole)) and this requires heating to higher temperatures of around 300-400° C., such as 310° C.

The majority of polymers that may be used for the substrate on which the solar cell layers are printed will not tolerate the temperatures required for cleavage of the solubilising groups of the active polymer. Glass may be used at such temperatures, but does not permit the resulting cell to be flexible or to withstand impacts easily. PEN (polyethylene naphthalate) may be used at such temperatures, but has the disadvantage of high cost, as well as being softer and more opaque than alternative polymer substrates.

It is therefore an object of the present invention to provide a method of thermocleaving a polymer layer on a substrate while not causing damage to over- or underlying heat-sensitive layers or the substrate. In this way, greater flexibility of manufacture of solar cells and other similarly-constructed devices may be achieved.

The present inventors have found that the use of a light source of an appropriate narrow wavelength range to heat a thermocleavable polymer layer can produce the required temperatures in that layer for rapid thermocleavage of the thermocleavable substance, without a detrimental level of heating of the underlying layers or substrate.

Accordingly, the present invention provides a method of thermocleaving a thermocleavable polymer layer which is in thermal contact with a heat sensitive component that is not tolerant of the temperature required for thermocleavage of the thermocleavable polymer layer, in which the thermocleavable polymer layer is illuminated with a light source having a wavelength range more strongly absorbed by the thermocleavable polymer and substantially less strongly absorbed by the heat sensitive component, such that the thermocleavable polymer layer reaches a temperature sufficient to cause thermocleavage of the polymer without causing detrimental heating to the heat sensitive component.

In order for the thermocleavable polymer layer to be heated to a sufficient temperature to undergo thermocleavage without causing detrimental heating to the heat sensitive component, it is preferred that the thermocleavable layer has an absorbance of around 1, i.e. an optical density such that 90% or more of the incident light is absorbed, whereas the heat sensitive component has an absorbance of much less than 1, such as less than 0.1, more preferably less than 0.05, with respect to the wavelength(s) of light used for the illumination. Illumination of the thermocleavable polymer layer using light of a wavelength range strongly absorbed by the polymer results in the light energy being converted to heat, thus raising the temperature of the film.

Usually, conduction will dissipate the heat energy not used in the thermocleavage of the polymer throughout the item in a short time, and the item will reach an equilibrium temperature. It is preferred that the heat capacity of the thermally cleavable polymer and the heat sensitive component together should be dominated by the heat sensitive component.

Preferably, the heat sensitive component should comprise at least 75% by weight or by volume of the combination of the heat sensitive component and the thermocleavable layer, more preferably at least 90% by weight or by volume, such as at least 95% by weight or by volume, most preferably at least 99% by weight or by volume. For example, where the heat sensitive component forms a layer on which the thermocleavable polymer layer is formed, the heat sensitive component layer may have a thickness in the range 25-1000 μm, preferably in the range 100-300 μm, whereas the thermocleavable polymer layer may typically have a thickness in the range 10-500 nm, more preferably in the range 75-250 nm. Thus, the heat sensitive component layer represents around 88%-99.99% by volume of the combination of the heat sensitive component layer and the thermocleavable layer, such as 99.75% by volume. Where the heat capacity of the combination of the heat sensitive component and the thermocleavable polymer layer is dominated by the heat capacity of the heat sensitive component, the residual heat in the thermocleavable layer is dissipated throughout the heat sensitive component but cannot cause a significant temperature rise of that component. For example, it is expected that, if the temperature of the thermocleavable layer is raised by 100° C. and the proportion of the combination of the heat sensitive component and the thermocleavable layer represented by the heat sensitive component is 99.75% by volume or weight, then the temperature of the whole system on reaching equilibrium would have been raised at most by around 0.25° C., under the assumption that the heat capacities for the two materials are the same and that no heat is lost to the surroundings.

Preferably, the heat sensitive component is a layer on which the thermocleavable polymer layer is formed.

Preferably, the heat sensitive component layer is a polymer film, such as a PET film.

It is preferred in some cases that the heating using the light source is carried out as a series of pulses of illumination. This also permits the temperature of the thermocleavable polymer layer to be raised without raising the overall temperature of the system significantly. The thermal conduction in polymers is usually in the range of 0.1-0.5 (W m⁻¹ K⁻¹) and the heat capacity is in the range of 1-2.5 (kJ kg⁻¹ K⁻¹), and so the timescale for thermal equilibrium after application of heat is expected to be of the order of 200-1000 ms. Thus, if a pulse of light of a lesser duration is used, the thermal diffusion of that pulse will be minimised, as the conduction will not be complete before the heating is ceased.

Thus, a thermocleavable polymer requiring a thermocleavage temperature higher than the highest tolerated temperature of the heat sensitive component may be thermocleaved without damage to the bulk of the heat sensitive component. The interface between the thermocleavable material and the heat sensitive material may melt.

Several processes influence the achievement of the desired temperature for thermocleavage in the active layer and they depend highly on the conditions used. These are: the speed of thermal conduction away from the heated layer, the heat capacities of the active layer and the heat sensitive layer, the energy required to carry out the thermocleavage, the heat of evaporation of the cleaved alkene, and heat exchange with the surroundings.

Suitably, the total energy delivery to the thermocleavable polymer layer per unit area is in the range 5-40 J cm⁻². Suitably, the total exposure time to the source of illumination of a unit area of the thermocleavable polymer layer is 25-1000 ms, such as 25-200 ms.

The item may be moved relative to the light source so as to treat areas larger than the field of illumination. The item to be heated may be in the form of a sheet or ribbon which may be wound from roll to roll. The illumination from the light source may be constant and the duration of the illumination of a given part of the item determined by the speed of movement of the item relative to the light source. Suitably, the light source may be pulsed to further tailor the exposure of the item to the illumination. The web speed (i.e. the speed of winding from roll to roll) is highly dependent on the amount of energy needed to be delivered to achieve the temperature required for thermocleavage of the thermocleavable polymer, and also on the output power of the illumination source.

Alternatively or additionally, the light source provides a field of illumination which is moved relative to the thermocleavable polymer layer. This may be achieved by movement of the light source, or by causing the field of illumination to move while the light source remains static, for example by the use of mirrors to scan the field of illumination across the surface of the thermocleavable polymer layer.

Suitably, the light source may be a laser or other monochromatic light source. The use of a laser has the advantage of providing very high intensity light, with the ability to focus the light on to a desired area of the item. In addition, it is possible to sweep or scan the light over the surface of the item. This allows selective patterning of the material, as the thermocleavable polymer layer may be thermocleaved in selected areas, and the unreacted polymer areas removed using a washing step. A laser light source can provide very high energy densities. Suitably, the laser heating is carried out as a series of pulses. Preferably, the pulses are in the millisecond range, as this allows full non-equilibrium heating to be achieved. The laser light source may suitably be a gas laser, a solid state laser, a free electron laser, or a dye laser.

Alternatively, the light source may be a high power LED array. The use of an LED light source has the advantages of lower cost and greater robustness compared with the use of a laser light source. In addition, a wide selection of wavelength ranges are accessible using LEDs. It may also be preferred to use LED sources rather than lasers from a safety point of view. Suitably, the LED heating is carried out as a series of pulses.

Preferably, the heat sensitive component is substantially transparent to the light used to heat the thermocleavable polymer layer.

Preferably, all components of the item except the thermocleavable polymer layer are also substantially transparent to the light used to heat the thermocleavable polymer layer.

Preferably, the item is a photovoltaic device, such as a solar cell.

Suitably, a mask may be interposed between the light source and the thermocleavable layer in order that only selected areas of the thermocleavable layer are thermocleaved upon illumination. Suitably, uncleaved areas of the thermocleavable layer may be removed by washing with a suitable solvent, such as chlorobenzene, after illumination.

Where the item is a photovoltaic device, the thermocleavable polymer is preferably a hole-conducting polymer forming part of the light harvesting layer of the device. Preferably, the polymer is a polythiophene (PT), an oligomer or a co-polymer of thiophene with other conjugated materials such as benzothiadiazole, thienopyrazine, thienothiophene, and/or carbazole or a poly(phenylenevinylene) (PPV) derivative. Preferably, the polymer has thermocleavable side chains. Preferably, the thermocleavable side chains are ester groups which may be cleaved to give the free carboxylic acid group. Suitably, the thermocleaving may also remove the carboxylate moiety. Particularly preferred polymers are poly(3-(2-methylhex-2-yl)oxycarbonyldithiophene) (P3 MHOCT), poly-[(3′-(2,5,9-trimethyldecan-2-yl)-oxy-carbonyl)-[2,2′; 5′,2″]terthiophene-1,5″-diyl)-co-(2,3-diphenylthieno[3,4-b]pyrazine-5,7-diyl)] (P3TMDCTTP) and poly-[(3′-(2,5,9-trimethyldecan-2-yl)-oxy-carbonyl)-[2,2′; 5′,2″]terthiophene-1,5″-diyl)-co-(benzo[c][1,2,5]thiadiazole-4,7-diyl)] (P3TMDCTBT). The synthesis and thermal cleavage of the first polymer has been published in J. Am. Chem. Soc. 2004, vol. 126, p. 9486-9487 by Jinsong Liu et al. The synthesis and cleavage of the second and third polymers is described below.

Preferably, where the thermocleavable polymers P3MOHCT or P3TMDCTTP and P3TMDCTBT are used, the light source has a wavelength in the range 400-550 nm, more preferably 450-550 nm, such as 475-532 nm. For example, a laser having a wavelength of 532 nm or a LED array having a wavelength of 466 nm may be used.

Suitably, the method may be used in conjunction with cooling means applied to the item such that the heat sensitive component is cooled while the thermocleavable polymer is heated. Any active cooling method compatible with the illumination technique to be used is suitable. An example of a suitable cooling means is a cooling roller, such as a metal roller with an inner cavity supplied with cool water. Alternatively, air cooling may be used. Preferably, the temperature of the cooling means is not less than 16° C., in order to avoid problems with condensation forming on the thermocleavable polymer layer or other components of the heated article. Such active cooling increases the steepness of the temperature gradient from the thermocleavable layer, in order to reduce the heating experienced by the heat sensitive component.

Suitably, the method may comprise illuminating the thermocleavable polymer layer from either or both faces. It is necessary where the illumination is from the unexposed side of the thermocleavable polymer layer for any components of the item through which the light is to pass in order to reach the thermocleavable polymer to be substantially transparent to the light wavelength range used. Where the layer is heated from both faces, the use of cooling means such as a cooling roller requires that the cooling roller is transparent to the light wavelength used for the illumination. For example, a cooling roller made of glass or quartz, having an inner cavity supplied with cooling water, may be used. When illuminating a web that is wound from roll to roll, the web speed may be doubled by applying illumination from both faces of the thermocleavable polymer layer, compared with illumination from one side alone.

Alternatively, in order to minimise the light energy required to thermocleave the thermocleavable polymer layer, it is contemplated that the heat sensitive component and the thermocleavable polymer layer may be heated to a temperature approaching the maximum tolerated temperature of the heat sensitive component. For example, for a layer of P3 MHOCT on a PET substrate, the two layers may be heated to 140° C., suitably in an oven, and the P3 MHOCT layer then illuminated according to the method of the invention in order to thermocleave the layer to P3CT or PT.

The present invention further provides an apparatus for thermocleaving a thermocleavable polymer layer which is in thermal contact with a heat sensitive component that is not tolerant of the temperature required for thermocleavage of the thermocleavable polymer layer, wherein the thermocleavable polymer layer is provided on a web comprising a heat sensitive component, the apparatus comprising:

an oven adapted to allow the passage of the web therethrough;
a source of illumination positioned to illuminate the web during or after its passage through the oven; and
a conveyor defining the path of the web for transporting the web through the oven and past the illumination source, comprising a reel on which the web is wound.

Preferably, the apparatus further comprises cooling means positioned to cool the web during or after illumination. Preferably, the cooling means is a cooling roller located opposite the illumination source.

Preferably, the conveyor further comprises a series of rollers (with tension control of the tension on the web) to move the web through the oven and into the presence of the illumination source.

Preferably, the illumination source comprises at least one LED, and most preferably the illumination source is an LED array. Preferably, the illumination source is positioned such that it is at most 5 cm from the web, such as at most 2 cm from the web.

Suitably, the apparatus may further comprise a printing station for printing the thermocleavable polymer layer on the web. Suitably, such a printing station may comprise a printer, means for surface treatment of the surface of the web to be printed, such as apparatus for corona treatment, and, optionally, means for drying the printed thermocleavable layer, such as an infrared heater. While the drying of the printed layer may be carried out by the oven, it may in some cases be preferred to provide separate means for drying the layer.

While the examples below are given in the context of the manufacture of photovoltaic cells, it will be appreciated by the skilled man that such methods may be applied wherever a thermocleavable substance is present on a heat sensitive component and it is desired to thermocleave the thermocleavable substance.

### BRIEF DESCRIPTION OF THE FIGURES

FIG. 1 shows a schematic diagram of the illumination of a layer of P3 MHOCT on PET.

FIG. 2 shows an apparatus for thermocleaving a polymer layer according to the invention.

FIG. 3 shows the change in UV-vis absorption spectrum on conversion of P2 MHOCT to P3CT on a 200 micron PET.

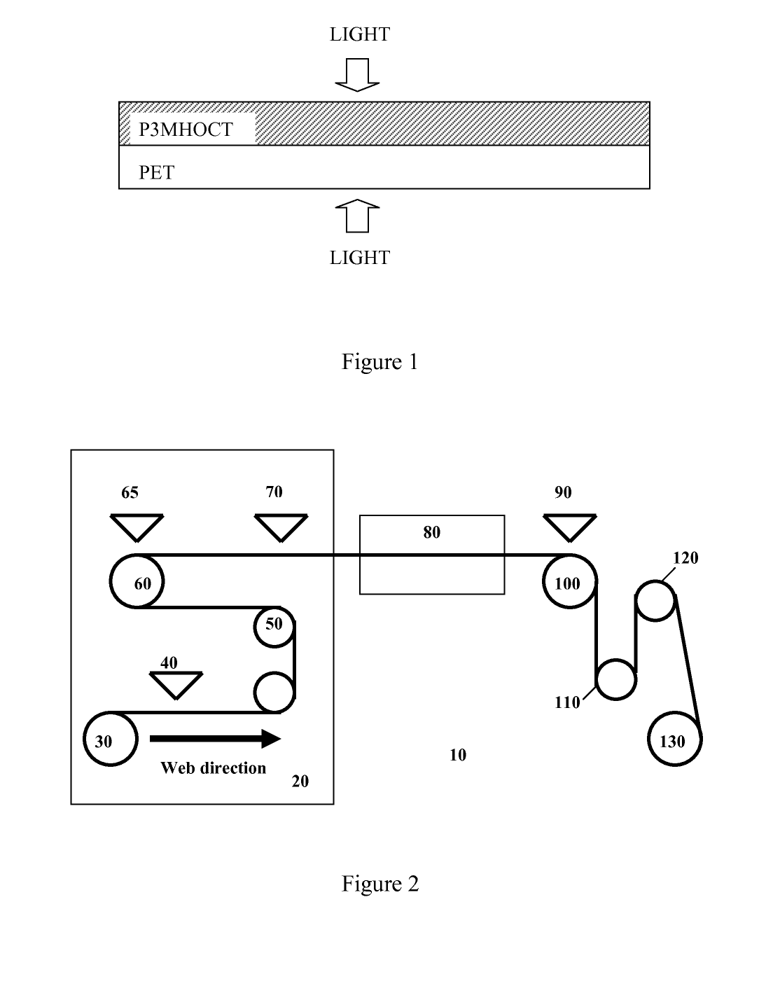

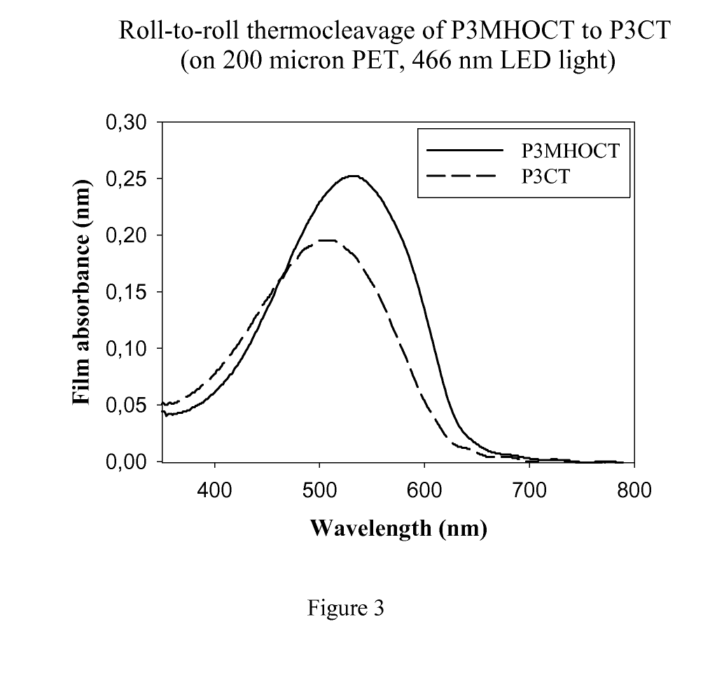

FIG. 1 represents schematically a layer of P3 MHOCT on PET. In reality, the P3 MHOCT layer is much thinner than the PET layer, and is shown of equal thickness in FIG. 1 for clarity. It can be seen that the P3 MHOCT film, which absorbs strongly in the wavelength range 400-550 nm (see FIG. 3), may be illuminated either from the face opposite the substrate, or through the PET substrate, or both, in order to heat the P3 MHOCT layer selectively. As PET is transparent to light in the wavelength range 400-550 nm, the P3 MHOCT layer may be illuminated from the substrate side, and there will be no absorption of the energy from a light source supplying light in the wavelength range 400-550 nm by the substrate to cause direct heating in the substrate.

Referring now to FIG. 2, there is shown an apparatus 10 suitable for the thermocleavage of a thermocleavable polymer layer on a heat-sensitive substrate formed as a web 35 that may be wound from roll to roll. The web 35 has a width of 280 mm, and is mounted on an unwinder 30, supported on tension rollers 50, 110, and collected after heating on a winder 130. The system may be run at web speeds of 0.2-2 m min⁻¹, and is operated in tension control with a tension on the web of 140 N. A printing station 20 is provided immediately downstream of unwinder 30, comprising a corona treatment apparatus 40, coating machine 65 and coating roller 60 for coating the thermocleavable polymer layer on to web 35, and IR lamp 70 in that order in the downstream direction. The coating machine used may suitably be a roll-to-roll coater, such as a modified basecoater from SolarCoatingMachinery GmbH, Germany. This coating machine has a roll width of 30 cm and a working width of 25 cm. Coating roller 60 may suitably be of 100 mm diameter, which permits the use of knife-over-edge coating, slot-die coating and gravure coating techniques. Downstream of the printing station 20 is provided oven 80, through which the web 35 passes. Oven 80 may suitably be heated by means of hot air, in particular by providing hot air inflow to heat the oven and air extraction to remove cooled air and any volatile substances which have vapourised during heating in the oven. The oven heats both surfaces of the web. A suitable operating temperature for the oven is 140° C. when the web is made from PET. Downstream of oven 80 is provided an LED lamp 90 and a cooling roller 100 which is in contact with the web 35 in the field of illumination of the LED lamp 90. The high power LED array 90 measures 11×273.5 mm and comprise an array of 182 lines (connected in parallel) of 7 diodes (connected in series). The array has a total of 1274 LED diodes that are attached to a silvered copper bar and the individual chips are wire bonded for connectivity. The copper bar is attached to a water cooled aluminium block. The LED array has a nominal current of 63.7 Amperes at 24 V and can be pulsed with higher currents at lower duty cycle. The system is typically operated at 33% duty cycle and 200 amperes of current, with a pulse length of 330 ms and thus a frequency of 1 Hz. The diode array 90 is positioned to be in close proximity to the web 35. The distance between the surface of the array 90 and web 35 is typically 1-10 mm, and may be adjusted depending on the film absorbance and web speed. Cooling roller 100 is suitably maintained at a temperature of 16° C., and may be water-cooled. A speed measuring roller 120 is provided to monitor the web speed in a suitable position, such as downstream of LED array 90. In addition, instrumentation such as temperature sensors, micropumps for controlling the coating process, and videocameras for viewing the web during the coating and drying process, in order to determine the thickness, evenness, dryness etc. of the coated layer, are provided (not shown). Optionally, a shadow mask (not shown) can be placed between the LED source 90 and the web 35 to pattern the illuminated area and thus the areas of the film that are cleaved. A washing step can then be used to remove uncleaved material after the illumination and thermocleavage.

In use, web 35 is mounted on unwinder 30 and passed over the tension roller 50, and coating roller 60, through oven 80, over cooling roller 100, tension roller 110, speed measuring roller 120 and attached to winder 130. The winder 130 and unwinder 30 then are operated such that the web passes over the speed measuring roller 120 at a speed of 0.2-2 m min⁻¹, with the tension rollers 50, 110 maintaining a tension of 140 N on the web. The web passes under the corona treatment apparatus, and undergoes corona treatment, then, after passing over tension roller 50, passes over coating roller 60 and under coating head 65, during which the thermocleavable polymer layer is applied to the web 35 by slot-die or knife-over-edge coating of a solution of the thermocleavable polymer. The coated web then passes under IR lamps 70, which dry the solvent from the coated layer. The web then enters the oven 80, and is heated to close to the maximum temperature tolerated by the web. For example, where the web is PET, the oven is maintained at 140° C. Any volatile compounds produced by the web or thermocleavable layer, for example any remaining solvent in the thermocleavable layer, are removed from the oven by the air extraction system. Once heated, the web then passes under LED array 90 and simultaneously over cooling roller 100. The web speed and the LED array operation parameters (i.e. LED power, pulse duration and frequency, and distance from the web) are chosen such that the thermocleavable layer is thermocleaved without detrimental heating of the web 35. The cooling action of the cooling roller 100 in contact with web 35 allows a more powerful illumination of the web than would be possible in its absence. Once the layer has been thermocleaved, the web passes over tension roller 110 and speed measuring roller 120, and is collected on winder 130.

### EXAMPLES

### General Methods

Regiorandom poly(3-(2-methylhex-2-yl)-oxy-carbonyldithiophene) (P3 MHOCT) was synthesised by the method of Jinsong Liu et al. (J. Am. Chem. Soc. 2004, vol. 126, p. 9486-9487). The synthesis is outlined below:

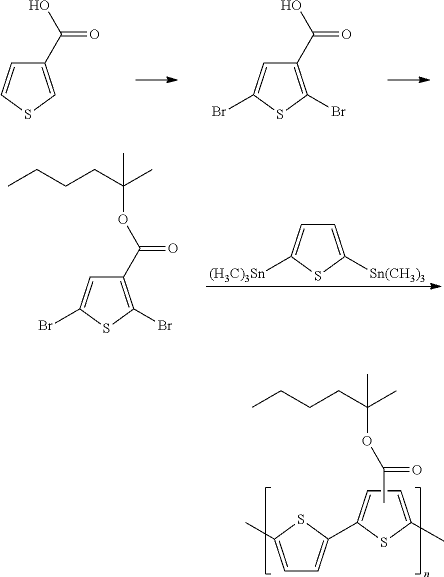

The P3 MHOCT as synthesised had the following properties: Mₙ=11300 g·mol⁻¹; M_{w}=36800 g·mol⁻¹; Mₚ=29800 g·mol⁻¹; PD=3.2. The P3 MHOCT was used as a solution in chlorobenzene, prepared by gentle shaking at room temperature. The use of elevated temperature was avoided in this step. The solution was stable for extended periods in a glove box or tightly sealed container.

P3TMDCTTP was synthesised as set out below:

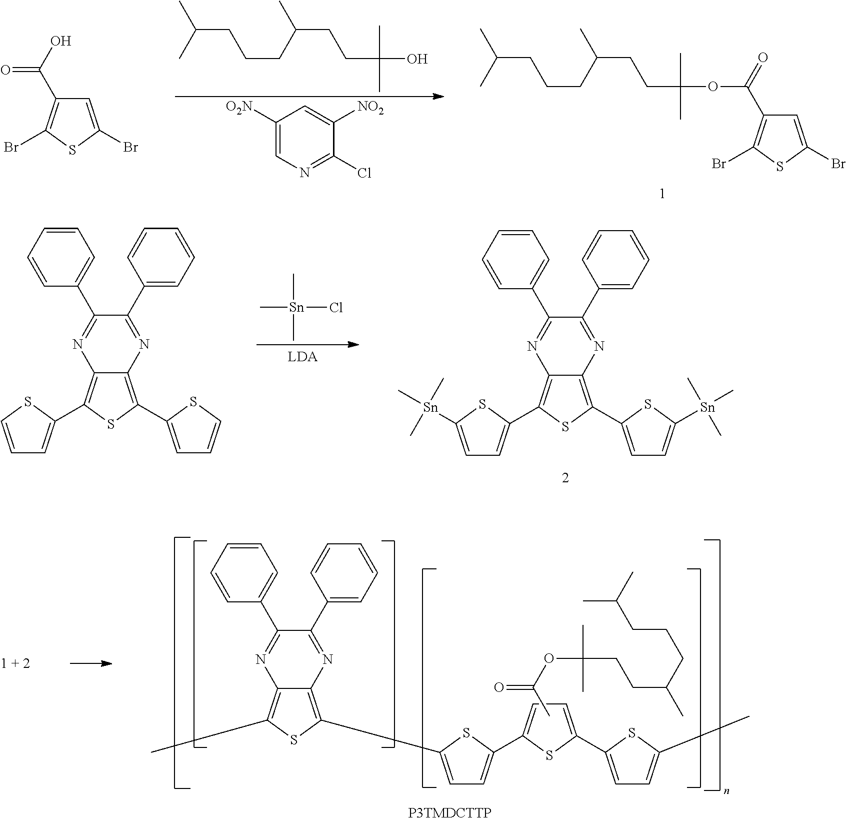

Synthetic procedure to the thermocleavable low band gap polymer P3TMDCTTP.

### Synthesis of (2,5,9-trimethyldecan-2-yl)-2,5-dibromothiophene-3-carboxylate

2,5-Dibromothiophene-3-carboxylic acid (10.0 g, 35 mmol) and 2-chloro-3,5-dinitropyridine (7.8 g, 38.5 mmol 1.1 eq.) were dissolved in dry pyridine under argon. The mixture was heated to approx. 40° C. for 30 minutes. 2,5,9-Trimethyl-decan-2-ol (7.7 g 38.5 mmol 1.1 eq) was added and the mixture is stirred at 120° C. overnight. After cooling to ambient temperature, the mixture was poured into a mixture of water (300 mL), light petroleum (300 mL) and NaHCO₃ (aq) (100 mL, 2M). The aqueous phase was extracted with light petroleum (3×100 ml), and the combined organic phases were dried over MgSO₄ and evaporated to give a light yellow oil. The product was purified by flash chromatography using heptane as base solvent and extracting the desired product with 2% ethyl acetate to give a colourless oil. Yield: 5.1 g (34%). ¹H NMR (CDCl₃): δ: 0.88 (t, 9H, J=7 Hz), 1.09-1.32 (m, 8H), 1.35-1.44 (m, 2H), 1.56 (s, 6H), 1.80-1.92 (m, 2H), 7.29 (s, 1H). ¹³C NMR (CDCl₃) δ: 19.7, 22.6, 22.7, 24.8, 26.1, 26.2, 28.0, 30.8, 33.0, 37.1, 38.2, 39.3, 85.0, 110.9, 118.0, 131.9, 133.4, 159.9.

### Synthesis of 2,3-diphenyl-5,7-bis(5-(trimethylstannyl)thiophen-2-yl)thieno[3,4-b]pyrazine

A solution of LDA was prepared as follows: THF (10 mL) was cooled to −10° C. and n-BuLi (1.6 M, in hexane, 10 mL, 16 mmol) was added dropwise. The mixture was stirred for 10 min. and di-isopropylamine (2.5 mL, 18 mmol) in THF (7.5 mL) was added drop wise. The mixture was stirred for 30 min. at −10° C. and used directly. This LDA solution (20 mL, 11 mmol, 5 eq.) was added drop wise to a solution of 2,3-diphenyl-di-thiophen-2-yl-thieno(3,4-b)pyrazine (1.0 g, 2.2 mmol) in THF (50 mL) at −78° C. A colour change from green to dark purple was observed. After 1 hour at −78° C. (2.6 g, 13 mmol) of trimethylstannyl chloride dissolved in dry THF (7 mL) was added over a period of 5 min. After the mixture had reached ambient temperature it was evaporated to dryness and recrystallized from heptane, to give a purple solid. Yield: 1.1 g (64%). ¹H NMR (CDCl₃): δ: 0.44 (s, 18H), 7.22 (d, 2H, J=4 Hz), 7.33-7.40 (m, 6H), 7.62 (dd, 4H, J1=8 Hz, J2=1 Hz), 7.87 (d, 2H, J=4 Hz). ¹³C NMR (CDCl₃) δ: −8.2, 124.9, 126.1, 128.0, 128.9, 130.0, 135.6, 137.5, 139.2, 139.7, 140.2, 152.7

### Synthesis of Regiorandom poly-[(3′-(2,5,9-trimethyldecan-2-yl)-oxy-carbonyl)-[2,2′; 5′,2″]terthiophene-1,5″-diyl)-co-(2,3-diphenylthieno[3,4-b]pyrazine-5,7-diyl)] (P3TMDCTTP)

2,3-diphenyl-5,7-bis(5-(trimethylstannyl)thiophen-2-yl)thieno[3,4-b]pyrazine (300 mg, 0.3854 mmol) and (2,5,9-trimethyldecan-2-yl)-2,5-dibromothiophene-3-carboxylate (180.5 mg, 0.3854 mmol) were dissolved in dry toluene under argon, Pd₂ dba₃ (12.5 mg,) and Tri-t-butylphosphonium tetrafluoroborate (25 mg) were added. N-methyldicyclohexyl amine (0.5 ml) was added after 5 min. The mixture was refluxed for 4 days. The mixture was concentrated to half the original volume on a rotary evaporator in vacuum and the residue was poured into 5 volumes of methanol. The precipitate was isolated by filtration, washed with methanol and dried to give a dark green powder. Yield: 198 mg (67%). ¹H NMR (CDCl₃): δ: 0-79-0.86 (m, 9H), 1.05-1.35 (m, 10H), 1.50-1.60 (m, 6H), 1.74-1.90 (m, 2H), 7.30-7.50 (m, 9H), 1.51-1.73 (m, 6H). SEC: Mₙ=1800, M_{w}=2900, Mₚ=2500, PD=1.6.

P3TMDCTBT was synthesised as set out below:

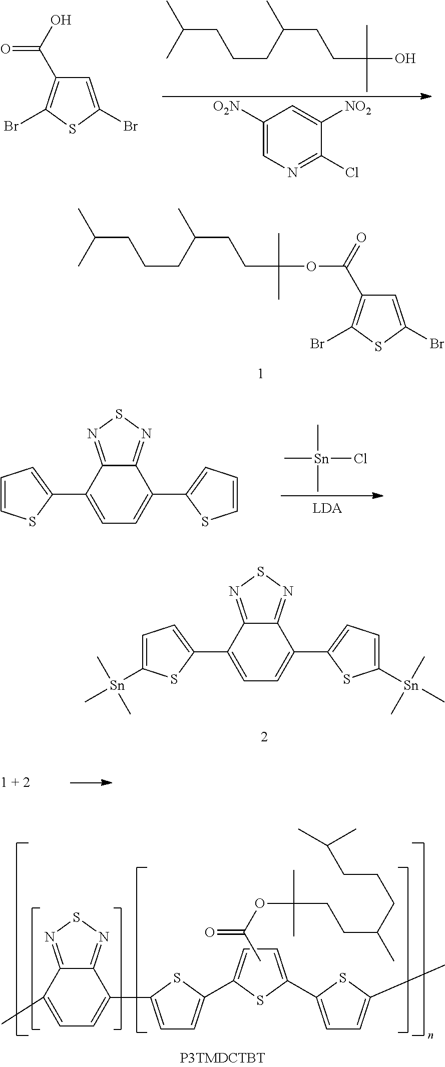

Synthetic procedure to the thermocleavable low band gap polymer P3TMDCTBT.

### Synthesis of 4,7-Bis-(5-trimethylstannanyl-thiophen-2-yl)-benzo[1,2,5]thiadiazole

A solution of LDA was prepared as follows: THF (10 mL) was cooled to −10° C. and n-BuLi (1.6 M, in hexane, 10 mL, 16 mmol) was added dropwise. The mixture was stirred for 10 min. and di-isopropylamine (2.5 mL, 18 mmol) in THF (7.5 mL) was added drop wise. The mixture was stirred for 30 min. at −10° C. and used directly. This LDA solution (30 mL, 16 mmol, 5 eq.) was added drop wise to a solution of 4,7-dithiophen-2-yl-benzo[1,2,5]thiadiazole (1.0 g, 3.3 mmol) in THF (50 mL) at −78° C. A colour change from orange to dark purple was observed. After 1 hour at −78° C. (3.6 g, 18 mmol) of trimethylstannyl chloride dissolved in dry THF (7 mL) was added over a period of 5 min. The colour changed back to dark orange. After the mixture had reached ambient temperature it was evaporated to dryness, washed with MeOH, which was decanted off and the product recrystallized from heptane, to give light orange crystals. Yield: 1.7 g (82%). ¹H NMR (CDCl₃): δ: 0.45 (s, 18H), 7.31 (d, 2H, J=7 Hz), 7.89 (s, 2H), 8.20 (d, 2H) J=4 Hz 7.87. ¹³C NMR (CDCl₃) δ: −8.2, 125.8, 128.4, 136.1, 140.3, 145.1, 152.7

### Synthesis of Regiorandom poly-[(3′-(2,5,9-trimethyldecan-2-yl)-oxy-carbonyl)-[2,2′; 5′,2″]terthiophene-1,5″-diyl)-co-(benzo[c][1,2,5]thiadiazole-4,7-diyl)] (P3TMDCTBT)

4,7-Bis-(5-trimethylstannanyl-thiophen-2-yl)-benzo[1,2,5]thiadiazole (153 mg, 0.2443 mmol) and (2,5,9-trimethyldecan-2-yl)-2,5-dibromothiophene-3-carboxylate (112 mg, 0.2443 mmol) were dissolved in dry toluene (25 ml) under argon, Pd₂ dba₃ (15 mg, 7 mol %) and Tri-o-tolylphosphine (40 mg, 56 mol %) were added. The mixture was refluxed overnight (20 h). The mixture was cooled to ambient temperature and was added dropwise into 5 volumes of stirred methanol. The precipitate was isolated by filtration, washed with methanol and dried to give a dark blue powder. Yield: 100 mg (67%). ¹H NMR (CDCl₃): δ: 0.68-0.95 (m, 9H), 0.98-1.37 (m, 9H), 1.40-1.69 (m, 7H), 1.70-1.90 (m, 2H), 7.20-7.60 (m (broad), 5H), 7.80-7.95 (m, 1H), 7.96-8.11 (m, 1H). SEC: Mₙ=1507, M_{w}=2444, Mₚ=2248, PD=1.62.

Zinc oxide nanoparticles were prepared by a procedure similar to that reported in Beek et al., J. Phys. Chem. B 109 (2005) p 9505. In a 3-litre conical flask, Zn(OAc)₂.2H₂O (29.7 g) was dissolved in methanol (1250 ml) and heated to 60° C. with stirring. KOH (15.1 g) dissolved in methanol (650 ml) and heated to 60° C. was added over 30 s. The mixture becomes cloudy towards the end of the addition. The mixture was heated to gentle reflux and after 2-5 min the mixture became clear and was stirred at this temperature for 3 h during which time precipitation starts. The magnetic stirrer bar was removed and the mixture left to stand at room temperature for 4 h. The mixture was carefully decanted leaving only the precipitate. The precipitate was then resuspended in methanol (1000 ml) and allowed to settle for 16 h. The mixture was then decanted carefully making sure that as much of the supernatant was removed as possible without the precipitate becoming dry. Chlorobenzene (35 ml) was added immediately and the precipitated nanoparticles dissolved giving a total volume of 45 ml. The typical concentration of a solution prepared in this manner was 200 mg·ml⁻¹, depending on the loss of nanoparticles during decanting of the supernatant. As an alternative to decantation, centrifuging of the mixture in methanol may be used, and this allowed the isolation of higher and more consistent yields of nanoparticles; however, the nanoparticles dissolved less easily and in a lower concentration in chlorobenzene when prepared by this method. The final solution of ZnO nanoparticles in chlorobenzene typically contains 10-20% methanol as free solvent and as solvent bound to the zinc oxide nanoparticles. The concentration of the ZnO nanoparticles in solution was determined by evaporation of the solvent from 1 ml of the solution at 80° C. for 1 h followed by careful weighing. The solution was stable for extended periods in a glove box or a tightly sealed container.

Solutions of P3 MHOCT or P3TMDCTTP and zinc nanoparticles in chlorobenzene were prepared by gentle shaking at room temperature, and were used within 24 h. Poorer results were obtained when older solutions were used. This is thought to be due to the basic nature of ZnO causing some hydrolysis of the ester groups of the polymer.

P3 MHOCT, P3TMDCTTP and P3TMDCTBT undergoes thermal cleavage to respectively P3CT, P3CTTP and P3CTBT at 210° C., and respectively to PT, PTTP and PTBT at 310° C.:

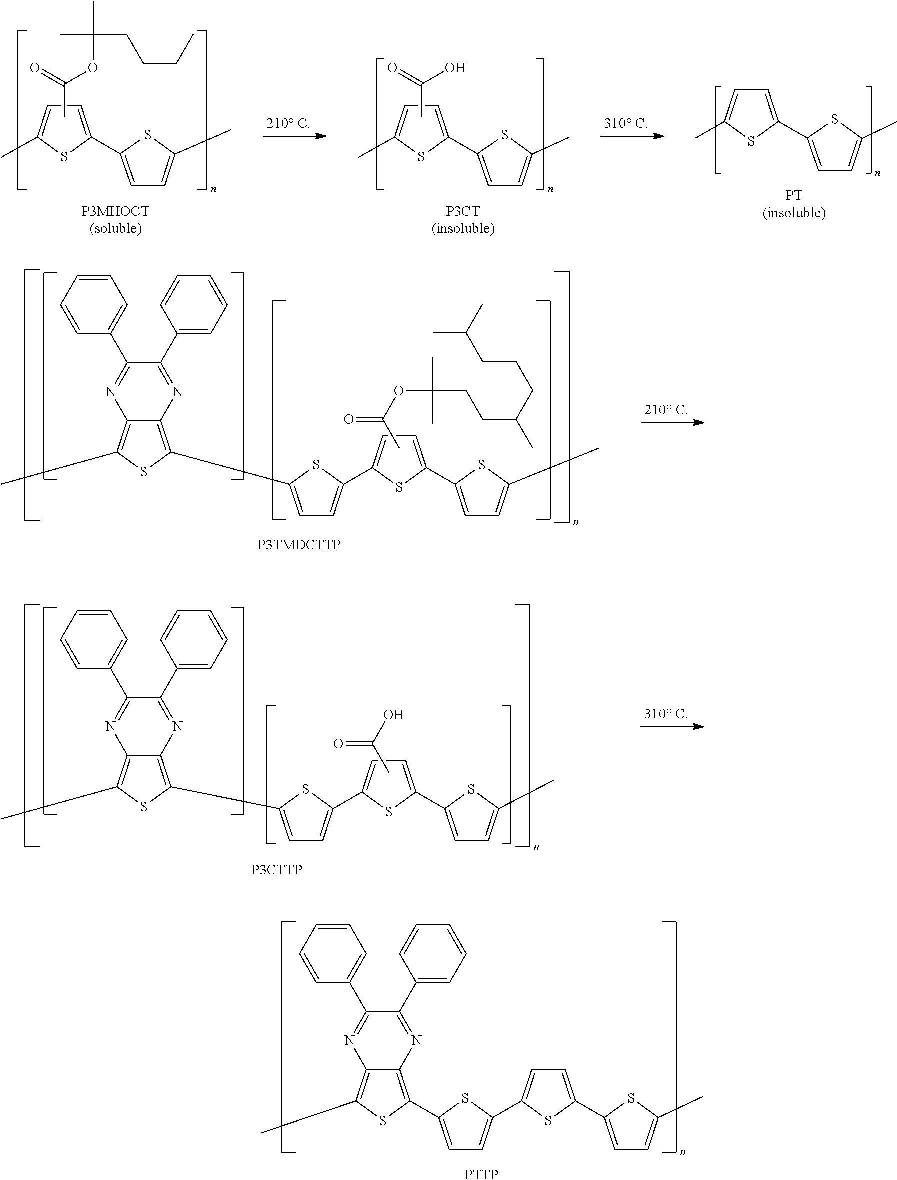

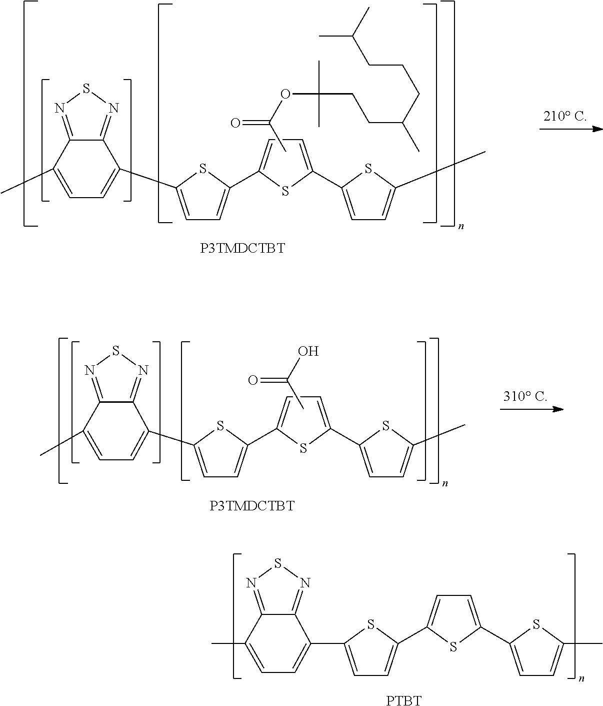

### Example 1

### Thermocleavage of P3 MHOCT on ITO/PET Using Laser Heating

An approximately 100 nm thick P3 MHOCT film was spincoated onto a substrate consisting of a 0.25 mm thick PET film with a 75 nm thick layer of ITO thereon. The film absorbance was around 1 for a 100 nm thick film of pure P3 MHOCT. The P3 MHOCT film on the substrate was mounted in a holder for illumination.

Illumination was carried out using a diode pumped Nd—YAG laser of 532 nm wavelength and having a maximum output power of 4.9 W. One 25 ms pulse with a spot size of 0.625 mm (resulting in an energy delivery to the layer of approximately 40 J cm⁻²) was delivered manually using an acousto-optic modulator, which was sufficient to convert P3 MHOCT through the entire 100 nm film to P3CT.

Conversion of the P3 MHOCT to P3CT was determined by rubbing the polymer film with a cotton bud soaked in chlorobenzene. The fully converted film remained insoluble in the solvent, whereas the unconverted or partially converted film was soluble in the solvent and was seen as a red colouring on the cotton bud. The conversion was also confirmed by observing the IR spectrum of the film using ATR-IR (attenuated total reflection-IR).

Illumination under the same conditions but using a single pulse with a duration of 100 ms giving approximately 160 J cm⁻² resulted in conversion to PT. Conversion to PT was determined by observing the IR spectrum of the film—the IR spectrum of PT does not contain a C═O stretch at ca 1700 cm⁻¹, whereas this peak is present in the spectrum of P3CT.

### Example 2

### Thermocleavage of P3 MHOCT/ZnO on ITO/PET Using Laser Heating

An approximately 140 nm thick P3 MHOCT/ZnO nanoparticle film was spincoated from a solution containing 50 mg mL⁻¹ ZnO and 25 mg mL⁻¹ P3 MHOCT onto a substrate consisting of a 0.25 mm thick PET film with a 75 nm thick layer of ITO thereon. The film absorbance was around 1. The P3 MHOCT film on the substrate was mounted in a holder for illumination.

Illumination was carried out using a diode pumped Nd—YAG laser of 532 nm wavelength and having a maximum output power of 4.9 W. One 25 ms pulse with a spot size of 0.625 mm (resulting in an energy delivery to the layer of approximately 40 J cm⁻²) was delivered manually using an acousto-optic modulator, which was sufficient to convert P3 MHOCT through the entire 140 nm film to P3CT.

Conversion of the P3 MHOCT to P3CT was determined by rubbing the polymer film with a cotton bud soaked in chlorobenzene. The fully converted film remained insoluble in the solvent, whereas the unconverted or partially converted film was soluble in the solvent and was seen as a red colouring on the cotton bud. The conversion was also confirmed by observing the IR spectrum of the film using ATR-IR (attenuated total reflection-IR).

Illumination under the same conditions but using a single pulse with a duration of 100 ms giving approximately 160 J cm⁻² resulted in conversion to PT. Conversion to PT was determined by observing the IR spectrum of the film—the IR spectrum of PT does not contain a C═O stretch at ca 1700 cm⁻¹, whereas this peak is present in the spectrum of P3CT.

### Example 3

### Thermocleavage of P3 MHOCT on ZnO/ITO/PET Using Laser Heating

An approximately 100 nm thick P3 MHOCT film was spincoated onto a substrate consisting of a 0.25 mm thick PET film with a 75 nm thick layer of ITO and a 30 nm thick film of ZnO nanoparticles thereon. The ZnO layer was prepared by spincoating a 50 mg mL⁻¹ chlorobenzene solution of ZnO nanoparticles at 1000 rpm followed by drying at 140° C. for 1 hour. The film absorbance was around 1. The P3 MHOCT film on the substrate was mounted in a holder for illumination.

Illumination was carried out using a diode pumped Nd—YAG laser of 532 nm wavelength and having a maximum output power of 4.9 W. One 25 ms pulse with a spot size of 0.625 mm (resulting in an energy delivery to the layer of approximately 40 J cm⁻²) was delivered manually using an acousto-optic modulator, which was sufficient to convert P3 MHOCT through the entire 100 nm film to P3CT.

Conversion of the P3 MHOCT to P3CT was determined by rubbing the polymer film with a cotton bud soaked in chlorobenzene. The fully converted film remained insoluble in the solvent, whereas the unconverted or partially converted film was soluble in the solvent and was seen as a red colouring on the cotton bud. The conversion was also confirmed by observing the IR spectrum of the film using ATR-IR.

Illumination under the same conditions but using a single pulse with a duration of 100 ms giving approximately 160 J cm⁻² resulted in conversion to PT. Conversion to PT was determined by observing the IR spectrum of the film—the IR spectrum of PT does not contain a C═O stretch at ca 1700 cm⁻¹, whereas this peak is present in the spectrum of P3CT.

As stated above, there are several processes that influence the achievement of the desired temperature for thermocleavage in the active layer and they depend highly on the experimental conditions. These are: the rate of thermal conduction away from the heated layer, the heat capacities of the active layer and the heat sensitive layer, the energy required to carry out the thermocleavage, the heat of evaporation of the cleaved alkene, and heat exchange with the surroundings. Ideally the heating of the thermocleavable layer should be instantaneous which requires a very short pulse of the order of 1-25 ms. From the thermal diffusion in most polymer materials we have a value in the range of 0.5-2′10⁻⁷ m² s⁻¹ given as the ratio between the heat conductivity and the product of the heat capacity and density. This implies that the timescale required for thermal equilibrium to be established after heat is applied to one surface of a film with a thickness of around 200 micron is of the order 200-1000 ms. This means that for the laser pulse experiment where the energy is delivered in 25 ms the dissipation of heat is not complete when the entire pulse has been delivered. In the case of LED pulses equilibrium is close to being established as the energy is practically delivered in 50-300 ms pulses. When the substrate is a good conductor of heat the required pulse length must be shorter and when the material is thinner the pulse length must be shorter. The energy required for thermocleaving a given material composition with a given thickness on a given substrate with a given thickness is thus most easily determined using laser pulses of different length and intensity and the subsequent analysis of the film at the spot of illumination.

### Example 4

### Thermocleavage of P3 MHOCT on PET Using LED Heating

An LED array having an optical output power of 6.5 W cm⁻² at 466 nm wavelength was used to illuminate the P3HMOCT layer of a device as prepared in Example 1. The device was prepared on a flexible sheet and was illuminated by winding from roll to roll through the illumination from a static LED array, using an apparatus according to the invention. The arrays gave an optical output power of 6.5 W cm⁻² at 466 nm wavelength. (Diode arrays with other emission wavelengths were also employed, but were not preferred as they suffered form a lower light output power.)

The LED arrays could be pulsed to give a power output of 20 W cm⁻² with a 33% duty cycle by tripling the current (thereby approximately tripling the output light intensity of the LEDs) and using water cooling of the LEDs. It was possible to operate at web speeds of 10 cm min⁻¹ while achieving full insolubility of the film, i.e. complete conversion of P3 MHOCT to P3CT. When the same illumination was carried out at lower web speeds (3 cm min⁻¹) it was possible to convert P3 MHOCT to PT.

Alternatively, the conversion of P3 MHOCT to P3CT or PT could be achieved using continuous illumination with the diode array at a web speed of respectively 4 cm min⁻¹ and 1 cm min⁻¹ and passing the web over a cooling roller having a temperature of 16° C.

### Example 5

### Thermocleavage of P3MOHCT on PET Using Heating and Illumination

By using the apparatus according to the invention to raise the temperature of the film on PET to 140° C. it was possible to achieve web speeds of respectively 30 cm min⁻¹ and 7 cm min⁻¹ for conversion to P3CT and PT on unsupported web using pulsed light as described for Example 4 above.

### Comparative Example

### Thermocleavage on PET Substrate at Low Temperature

A flexible plastic (polyethyleneterephthalate, PET) substrate with an overlayer of ITO was used as the base of the device.

ZnO nanoparticles were prepared as a 50 mg mL⁻¹ solution in the thermocleavable solvent 2,5-dimethylhexyloxy-phenyloxy-carbonate (WS-1) (WO2007/118850). The solution was prepared by adding to WS-1 a stock solution of ZnO nanoparticles (200 mg mL⁻¹) that had been stabilised with methoxyethoxy acetic acid (MEA) (40 mg mL⁻¹) in a 80:20 (v/v) solution of chlorobenzene and methanol. After mixing the chlorobenzene and methanol was evaporated giving the final solution of ZnO in WS-1.

This solution was screen printed onto the PET-ITO base. The screen printing was performed with a 140 mesh screen and the squeegee speed was 550 mm s⁻¹. The printed film was dried at 70° C. for 1 hour and 150° C. for 2 hours (or 140° C. for 4 hours) and left in the ambient air for 20 hours to become insoluble. The thermocleavable polymer layer was then printed as a solution in WS-1 that was 25 mg mL⁻¹ P3 MHOCT, 50 mg mL⁻¹ ZnO and 10 mg mL⁻¹ MEA. The solution was prepared by dissolving P3 MHOCT in chlorobenzene followed by microfiltering and mixing with MEA stabilised ZnO nanoparticles in WS-1. Evaporation of the chlorobenzene and methanol gave the final screen printing formulation that was screen printed as above through a 140 mesh screen with a squeegee speed of 550 mm s⁻¹. The film was dried at 150° C. for 2 hours (or 140° C. for 4 hours) in order to convert the P3 MHOCT to P3CT.

1. A method of thermocleaving a thermocleavable polymer layer which is in thermal contact with a heat sensitive component that is not tolerant of the temperature required for thermocleavage of the thermocleavable polymer layer, in which the thermocleavable polymer layer is illuminated with a light source having a wavelength range more strongly absorbed by the thermocleavable polymer and substantially less strongly absorbed by the heat sensitive component, such that the thermocleavable polymer layer reaches a temperature sufficient to cause thermocleavage of the polymer without causing detrimental heating to the heat sensitive component.

2. The method of claim 1, wherein the thermocleavable layer has an absorbance of around 1, and wherein the heat sensitive component has an absorbance of less than 0.1.

3. The method of claim 1, wherein the heat sensitive component represents at least 75% by weight or by volume of the combined weight or volume of the heat sensitive component and the thermocleavable layer.

4. The method of claim 1, wherein the heat sensitive component is a polymer film on which the thermocleavable polymer layer is provided.

5. The method of claim 1, wherein the illumination is carried out in a series of pulses.

6. The method of claim 5, wherein the pulse duration is in the millisecond range.

7. The method of claim 1, wherein the light source is a laser.

8. The method of claim 1, wherein the light source is a high power LED array.

9. The method of claim 1, wherein the light source provides a field of illumination which is moved relative to the thermocleavable polymer layer.

10. The method of claim 1, wherein the heat sensitive component is substantially transparent to the light wavelength range used to illuminate the thermocleavable polymer layer.

11. The method of claim 10, wherein the thermocleavable polymer layer is illuminated from both faces.

12. The method of claim 1, wherein the thermocleavable polymer layer and the heat sensitive component are comprised in a photovoltaic device.

13. The method of claim 12, wherein the thermocleavable polymer is a hole-conducting polymer.

14. The method of claim 13, wherein the thermocleavable polymer is a polythiophene (PT) or poly(phenylenevinylene) (PPV) derivative.

15. The method of claim 14, wherein the polymer has thermocleavable side chains which are ester groups that may be cleaved to give the free carboxylic acid group.

16. The method of claim 15, wherein the polymer is P3MOHCT, P3TMDCTTP or P3TMDCTBT.

17. The method of claim 16, wherein the light source has a wavelength in the range 400-550 nm.

18. The method of claim 1, wherein the heat sensitive component is cooled during illumination.

19. The method of claim 1, wherein a mask is interposed between the light source and the thermocleavable polymer layer in order that selected areas of the thermocleavable polymer layer are illuminated.

20. The method of claim 20, further comprising a step of washing the thermocleavable polymer layer after illumination to remove uncleaved areas of the layer.

21.-27. (canceled)
